(19) United States
(12) Patent Application Publication
(10) Pub. No.: US 2022/0298640 A1
(43) Pub. Date: Sep. 22, 2022

(54) Substrate Processing Apparatus, Nozzle Adapter, Method of Manufacturing Semiconductor Device and Substrate Processing Method

(71) Applicant: Kokusai Electric Corporation, Tokyo (JP)

(72) Inventors: Hironobu SHIMIZU, Toyama (JP); Satoru MURATA, Toyama (JP); Shinya MORITA, Toyama (JP)

(21) Appl. No.: 17/685,137

(22) Filed: Mar. 2, 2022

(30) Foreign Application Priority Data
Mar. 17, 2021 (JP) 2021-044186

(51) Int. Cl. C23C 16/455

(52) U.S. Cl. CPC C23C 16/45563

(57) ABSTRACT

There is provided a technique capable of reducing a tilt of a nozzle. According to one aspect of the technique, there is provided a substrate processing apparatus including: a process vessel constituted by a reaction tube and a manifold supporting the reaction tube from thereunder and in which a substrate is processed; a nozzle through which a process gas is supplied to the substrate; a metal adapter configured to hold the nozzle vertically in the process vessel; a support base arranged below the metal adapter and fixed to the manifold; and a fixing bolt engaging with the support base and screwed into the metal adapter.

### CROSS REFERENCE TO RELATED APPLICATIONS

This application claims foreign priority under 35 U.S.C. § 119(a)-(d) to Application No. JP 2021-044186 filed on Mar. 17, 2021, the entire contents of which are hereby incorporated by reference.

### TECHNICAL FIELD

The present disclosure relates to a substrate processing apparatus, a nozzle adapter, a method of manufacturing a semiconductor device and a substrate processing method.

### BACKGROUND

In a substrate processing of a manufacturing process of a semiconductor device, for example, a substrate processing apparatus such as a vertical type substrate processing apparatus capable of batch-processing a plurality of substrates may be used. In the vertical type substrate processing apparatus, a nozzle (also referred to as an “injector”) through which a process gas is supplied is inserted into a gas introduction port provided in a manifold and fixed to the gas introduction port. Thereby, the nozzle is installed so as to extend in a reaction tube along a vertical direction. When the nozzle is installed tilted in a front-rear direction, a tilt of the nozzle may be adjusted such that the nozzle is installed so as to extend in the vertical direction by pushing a nozzle mounting structure (nozzle base) upward by an adjustment structure provided on a pedestal. In the present specification, a direction toward a center of a process vessel constituted by the reaction tube and the manifold may be referred to as a “front direction” or a “front side”, and a direction away from the center of the process vessel may be referred to as a “rear direction” or a “rear side”.

The nozzle base supports no more than two points, that is, the adjustment structure and a cylindrical structure inserted in the gas introduction port. The nozzle base is vulnerable to tilting in a left-right direction when the nozzle is viewed from front. Therefore, the nozzle may tilt in the left-right direction, and may come into contact with one of other nozzles arranged in multiple rows or with the process vessel.

### SUMMARY

According to the present disclosure, there is provided a technique capable of reducing a tilt of a nozzle.

According to one or more embodiments of the present disclosure, there is provided a technique related to a substrate processing apparatus including: a process vessel constituted by a reaction tube and a manifold supporting the reaction tube from thereunder and in which a substrate is processed; a nozzle through which a process gas is supplied to the substrate; a metal adapter configured to hold the nozzle vertically in the process vessel; a support base arranged below the metal adapter and fixed to the manifold; and a fixing bolt engaging with the support base and screwed into the metal adapter.

### BRIEF DESCRIPTION OF THE DRAWINGS

FIG. 1 is a diagram schematically illustrating a vertical cross-section of a vertical type process furnace of a substrate processing apparatus preferably used in one or more embodiments of the present disclosure.

FIG. 2 is a diagram schematically illustrating a horizontal cross-section taken along the line A-A of the vertical type process furnace of the substrate processing apparatus shown in FIG. 1 preferably used in the embodiments of the present disclosure.

FIG. 3 is a diagram schematically illustrating the vicinity of a nozzle preferably used in the embodiments of the present disclosure when viewed from a side of the nozzle.

FIG. 4 is a diagram schematically illustrating a perspective view of a metal adapter preferably used in the embodiments of the present disclosure.

FIG. 5 is a diagram schematically illustrating a vertical cross-section of the metal adapter preferably used in the embodiments of the present disclosure.

FIG. 6 is a diagram schematically illustrating a front view of a lower portion of a process vessel preferably used in the embodiments of the present disclosure.

FIG. 7 is a flow chart schematically illustrating a nozzle mounting method preferably used in the embodiments of the present disclosure.

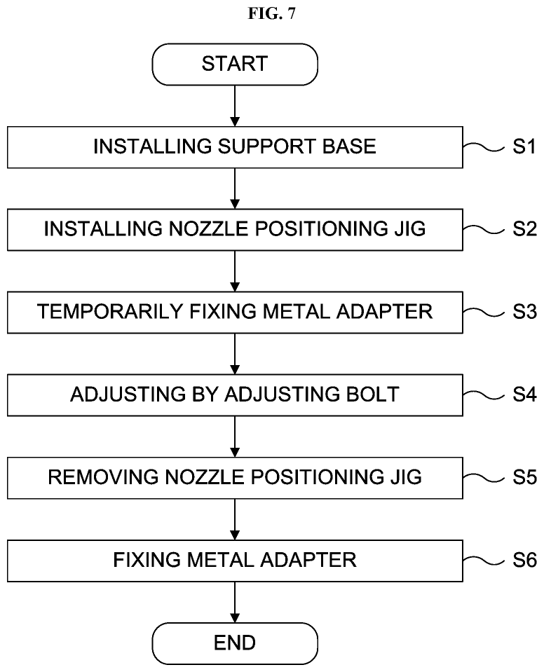

FIG. 8 is a diagram schematically illustrating a vertical cross-section of a metal adapter preferably used in another embodiment of the present disclosure.

FIG. 9 is a diagram schematically illustrating a front view of a lower portion of a process vessel preferably used in another embodiment of the present disclosure.

FIG. 10 is a flow chart schematically illustrating a method of manufacturing a semiconductor device preferably used in the embodiments of the present disclosure.

### DETAILED DESCRIPTION

### Embodiments

Hereinafter, one or more embodiments (also simply referred to as “embodiments”) according to the technique of the present disclosure will be described with reference to the drawings. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

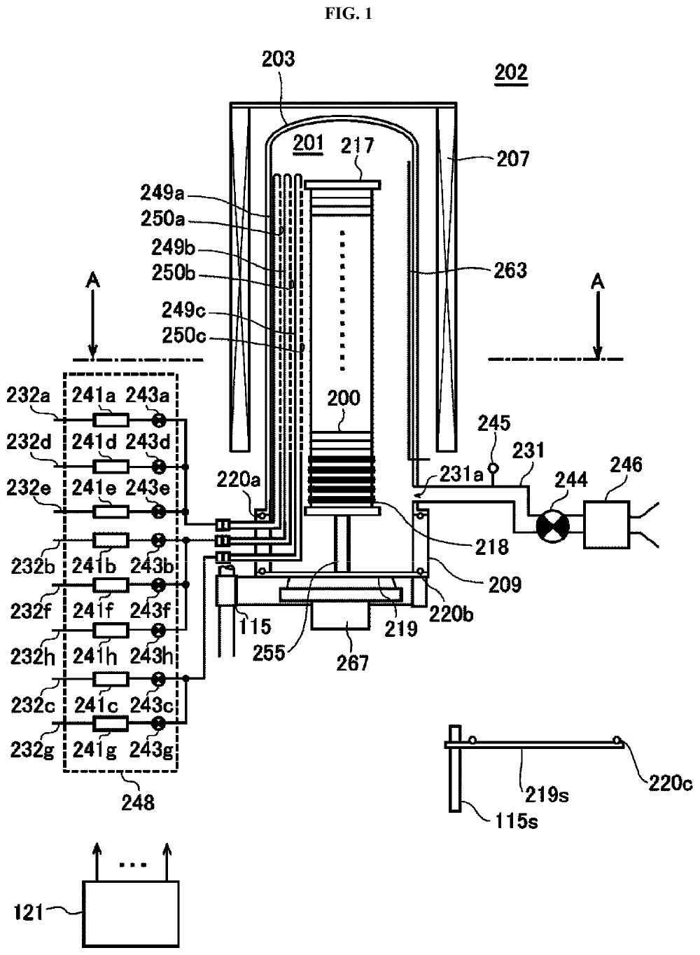

As shown in FIG. 1, a substrate processing apparatus according to the present embodiments includes a process furnace 202. The process furnace 202 is provided with a heater 207 serving as a temperature regulator (which is a heating structure or a heating system). The heater 207 is of a cylindrical shape, and is vertically installed while being supported by a support plate (not shown). The heater 207 also functions as an activator (also referred to as an “exciter”) capable of activating (exciting) a gas such as a process gas by a heat.

A reaction tube 203 is provided in an inner side of the heater 207 to be aligned in a manner concentric with the heater 207. For example, the reaction tube 203 is made of a heat resistant material such as quartz (SiO₂) and silicon carbide (SiC). The reaction tube 203 is of a cylindrical shape with a closed upper end and an open lower end. A manifold 209 is provided under the reaction tube 203 to be aligned in a manner concentric with the reaction tube 203. For example, the manifold 209 is made of a metal such as stainless steel (SUS). The manifold 209 is of a cylindrical shape with open upper and lower ends. The upper end of the manifold 209 is engaged with the lower end of the reaction tube 203 so as to support the reaction tube 203. An O-ring 220a serving as a seal is provided between the manifold 209 and the reaction tube 203. Similar to the heater 207, the reaction tube 203 is installed vertically. A process vessel (also referred to as a “reaction vessel”) is constituted mainly by the reaction tube 203 and the manifold 209. A process chamber 201 is provided in a hollow cylindrical portion of the process vessel. The process chamber 201 is configured to accommodate a plurality of wafers including a wafer 200 serving as a substrate. Hereinafter, the plurality of wafers including the wafer 200 may also be simply referred to as “wafers 200”. The wafers 200 are processed in the process chamber 201.

Nozzles 249a, 249b and 249c are provided in the process chamber 201 so as to penetrate a side wall of the manifold 209. The nozzles 249a, 249b and 249c serve as a first supplier (which is a first supply structure), a second supplier (which is a second supply structure) and a third supplier (which is a third supply structure), respectively. The nozzles 249a, 249b and 249c may also be referred to as a first nozzle, a second nozzle and a third nozzle, respectively. For example, each of the nozzles 249a, 249b and 249c is made of a heat resistant material such as quartz and silicon carbide. Gas supply pipes 232a, 232b and 232c are connected to the nozzles 249a, 249b and 249c, respectively, through a metal adapter 60 described later. The nozzles 249a, 249b and 249c are different nozzles, and each of the nozzles 249a and 249c is provided adjacent to the nozzle 249b.

Mass flow controllers (also simply referred to as “MFCs”) 241a, 241b and 241c serving as flow rate controllers (flow rate control structures) and valves 243a, 243b and 243c serving as opening/closing valves are sequentially installed at the gas supply pipes 232a, 232b and 232c, respectively, in this order from upstream sides to downstream sides of the gas supply pipes 232a, 232b and 232c in a gas flow direction. Gas supply pipes 232d and 232e are connected to the gas supply pipe 232a at a downstream side of the valve 243a of the gas supply pipe 232a. Gas supply pipes 232f and 232h are connected to the gas supply pipe 232b at a downstream side of the valve 243b of the gas supply pipe 232b. A gas supply pipe 232g is connected to the gas supply pipe 232c at a downstream side of the valve 243c of the gas supply pipe 232c. MFCs 241d, 241e, 241f, 241g and 241h and valves 243d, 243e, 243f, 243g and 243h are sequentially installed at the gas supply pipes 232d, 232e, 232f, 232g and 232h, respectively, in this order from upstream sides to downstream sides of the gas supply pipes 232d, 232e, 232f, 232g and 232h in the gas flow direction. Each of the gas supply pipes 232a through 232h is made of a metal material such as stainless steel (SUS).

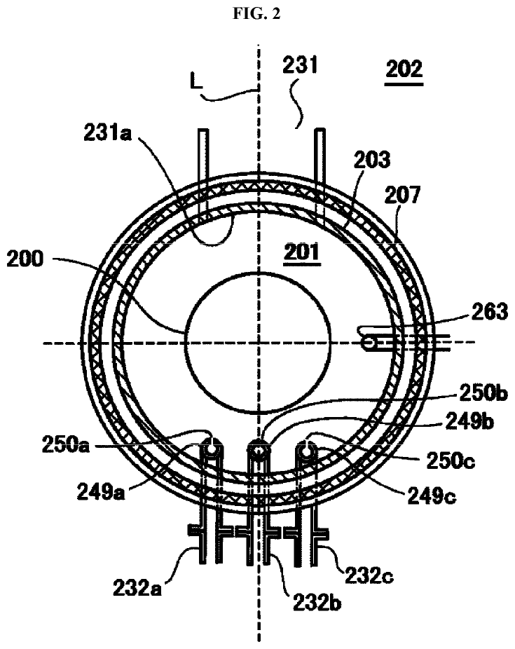

As shown in FIG. 2, each of the nozzles 249a, 249b and 249c is installed in an annular space provided between an inner wall of the reaction tube 203 and the wafers 200 when viewed from above, and extends upward from a lower portion toward an upper portion of the reaction tube 203 along the inner wall of the reaction tube 203 (that is, extends upward along a wafer arrangement direction). That is, each of the nozzles 249a, 249b and 249c is installed in a region that is located beside and horizontally surrounds a wafer arrangement region in which the wafers 200 are arranged (stacked) so as to extend along the wafer arrangement region. When viewed from above, the nozzle 249b is arranged so as to face an exhaust port 231a described later along a straight line (denoted by “L” shown in FIG. 2) with a center of the wafer 200 transferred (loaded) into the process chamber 201 interposed therebetween. The straight line L is a straight line passing through the nozzle 249b and a center of the exhaust port 231a. The nozzles 249a and 249c are arranged along the inner wall of the reaction tube 203 (an outer peripheral portion of the wafer 200) such that the straight line L is interposed therebetween. The straight line L is also a straight line passing through the nozzle 249b and the center of the wafer 200. That is, it can be said that the nozzle 249c is provided opposite to the nozzle 249a with respect to the straight line L interposed therebetween. The nozzles 249a and 249c are arranged to be line-symmetric with respect to the straight line L as an axis of symmetry. A plurality of gas supply holes 250a, a plurality of gas supply holes 250b and a plurality of gas supply holes 250c are provided at side surfaces of the nozzles 249a, 249b and 249c, respectively. Gases are supplied through the gas supply holes 250a, the gas supply holes 250b and the gas supply holes 250c. The gas supply holes 250a, the gas supply holes 250b and the gas supply holes 250c are open toward the exhaust port 231a when viewed from above, and are configured such that the gases are supplied toward the wafer 200 through the gas supply holes 250a, the gas supply holes 250b and the gas supply holes 250c. The gas supply holes 250a, the gas supply holes 250b and the gas supply holes 250c are provided from the lower portion toward the upper portion of the reaction tube 203.

A film-forming inhibitory gas is supplied into the process chamber 201 through the gas supply pipe 232a provided with the MFC 241a and the valve 243a and the nozzle 249a.

A source gas is supplied into the process chamber 201 through the gas supply pipe 232b provided with the MFC 241b and the valve 243b and the nozzle 249b.

A reactive gas is supplied into the process chamber 201 through the gas supply pipe 232c provided with the MFC 241c and the valve 243c and the nozzle 249c. The reactive gas may contain a substance serving as a halogen-free substance described later. Therefore, the halogen-free substance may be supplied into the process chamber 201 through the gas supply pipe 232c provided with the MFC 241c and the valve 243c and the nozzle 249c.

A catalyst gas is supplied into the process chamber 201 through the gas supply pipe 232d provided with the MFC 241d and the valve 243d, the gas supply pipe 232a and the nozzle 249a.

An inert gas is supplied into the process chamber 201 through the gas supply pipes 232e, 232f and 232g provided with the MFCs 241e, 241f and 241g and the valves 243e, 243f and 243g, respectively, the gas supply pipes 232a, 232b and 232c and the nozzles 249a, 249b and 249c.

The halogen-free substance is supplied into the process chamber 201 through the gas supply pipe 232h provided with the MFC 241h and the valve 243h, the gas supply pipe 232b and the nozzle 249b.

A film-forming inhibitory gas supplier (which is a film-forming inhibitory gas supply structure or a film-forming inhibitory gas supply system) is constituted mainly by the gas supply pipe 232a, the MFC 241a and the valve 243a. A source gas supplier (which is a source gas supply structure or a source gas supply system) is constituted mainly by the gas supply pipe 232b, the MFC 241b and the valve 243b. A reactive gas supplier (which is a reactive gas supply structure or a reactive gas supply system) is constituted mainly by the gas supply pipe 232c, the MFC 241c and the valve 243c. A catalyst gas supplier (which is a catalyst gas supply structure or a catalyst gas supply system) is constituted mainly by the gas supply pipe 232d, the MFC 241d and the valve 243d. An inert gas supplier (which is an inert gas supply structure or an inert gas supply system) is constituted mainly by the gas supply pipes 232e, 232f and 232g, the MFCs 241e, 241f and 241g and the valves 243e, 243f and 243g. A halogen-free substance supplier (which is a halogen-free substance supply structure or a halogen-free substance supply system) is constituted mainly by the gas supply pipe 232h, the MFC 241h and the valve 243h.

In the present embodiments, the source gas, the reactive gas and the catalyst gas serve as a film-forming gas (that is, the process gas). Therefore, the source gas supplier, the reactive gas supplier and the catalyst gas supplier may also be collectively or individually referred to as a “film-forming gas supplier” which is a film-forming gas supply structure or a film-forming gas supply system. In addition, the reactive gas may act as a halogen-free substance. Therefore, the reactive gas supplier may also be referred to as the “halogen-free substance supplier”. That is, the halogen-free substance supplier may be constituted mainly by the gas supply pipe 232c, the MFC 241c and the valve 243c.

Any one or an entirety of the gas suppliers described above may be embodied as an integrated gas supply system 248 in which the components such as the valves 243a through 243h and the MFCs 241a through 241h are integrated. The integrated gas supply system 248 is connected to the respective gas supply pipes 232a through 232h. An operation of the integrated gas supply system 248 to supply various gases to the gas supply pipes 232a through 232h, for example, operations such as an operation of opening and closing the valves 243a through 243h and an operation of adjusting flow rates of the gases through the MFCs 241a through 241h may be controlled by a controller 121 which will be described later. The integrated gas supply system 248 may be embodied as an integrated structure (integrated unit) of an all-in-one type or a divided type. The integrated gas supply system 248 may be attached to or detached from the components such as the gas supply pipes 232a through 232h on a basis of the integrated structure. Operations such as maintenance, replacement and addition of the integrated gas supply system 248 may be performed on a basis of the integrated structure.

The exhaust port 231a through which an inner atmosphere of the process chamber 201 is exhausted is provided at a lower side wall of the reaction tube 203. As shown in FIG. 2, the exhaust port 231a is arranged at a location so as to face the nozzles 249a, 249b and 249c (the gas supply holes 250a, the gas supply holes 250b and the gas supply holes 250c) with the wafer 200 interposed therebetween when viewed from above. The exhaust port 231a may be provided so as to extend upward from the lower portion toward the upper portion of the reaction tube 203 along a side wall of the reaction tube 203 (that is, along the wafer arrangement region). An exhaust pipe 231 is connected to the exhaust port 231a. A vacuum pump 246 serving as a vacuum exhaust apparatus is connected to the exhaust pipe 231 through a pressure sensor 245 and an APC (Automatic Pressure Controller) valve 244. The pressure sensor 245 serves as a pressure detector (pressure detection structure) to detect an inner pressure of the process chamber 201, and the APC valve 244 serves as a pressure regulator (pressure adjusting structure). With the vacuum pump 246 in operation, the APC valve 244 may be opened or closed to vacuum-exhaust the process chamber 201 or stop the vacuum exhaust. With the vacuum pump 246 in operation, the inner pressure of the process chamber 201 may be adjusted by adjusting an opening degree of the APC valve 244 based on pressure information detected by the pressure sensor 245. An exhauster (which is an exhaust structure or an exhaust system) is constituted mainly by the exhaust pipe 231, the APC valve 244 and the pressure sensor 245. The exhauster may further include the vacuum pump 246.

A seal cap 219 serving as a furnace opening lid capable of airtightly sealing a lower end opening of the manifold 209 is provided under the manifold 209. The seal cap 219 is made of a metal material such as SUS, and is of a disk shape. An O-ring 220b serving as a seal is provided on an upper surface of the seal cap 219 so as to be in contact with the lower end of the manifold 209. A rotator 267 configured to rotate a boat 217 described later is provided under the seal cap 219. A rotating shaft 255 of the rotator 267 is connected to the boat 217 through the seal cap 219. As the rotator 267 rotates the boat 217, the wafers 200 accommodated in the boat 217 are rotated. The seal cap 219 is elevated or lowered in the vertical direction by a boat elevator 115 serving as an elevator provided outside the reaction tube 203. The boat elevator 115 serves as a transfer device (which is a transfer structure or a transfer system) that loads the boat 217 and the wafers 200 accommodated in the boat 217 into the process chamber 201 or unloads the boat 217 and the wafers 200 accommodated in the boat 217 out of the process chamber 201 by elevating or lowering the seal cap 219.

A shutter 219s serving as a furnace opening lid capable of airtightly sealing the lower end opening of the manifold 209 is provided under the manifold 209. The shutter 219s is configured to close the lower end opening of the manifold 209 when the seal cap 219 is lowered by the boat elevator 115 and the boat 217 is unloaded out of the process chamber 201. For example, the shutter 219s is made of a metal material such as SUS, and is of a disk shape. An O-ring 220c serving as a seal is provided on an upper surface of the shutter 219s so as to be in contact with the lower end of the manifold 209. An opening and closing operation of the shutter 219s such as an elevation operation and a rotation operation is controlled by a shutter opener/closer (which is a shutter opening/closing structure) 115s.

The boat 217 serving as a substrate retainer is configured such that the wafers 200 (for example, 25 wafers to 200 wafers) are accommodated (or supported) in the vertical direction in the boat 217 while the wafers 200 are horizontally oriented with their centers aligned with one another with a predetermined interval therebetween in a multistage manner. For example, the boat 217 is made of a heat resistant material such as quartz and SiC. For example, a plurality of heat insulation plates 218 made of a heat resistant material such as quartz and SiC are supported at a lower portion of the boat 217 in a multistage manner.

A temperature sensor 263 serving as a temperature detector is installed in the reaction tube 203. A state of electric conduction to the heater 207 is adjusted based on temperature information detected by the temperature sensor 263 such that a desired temperature distribution of an inner temperature of the process chamber 201 can be obtained. The temperature sensor 263 is provided along the inner wall of the reaction tube 203.

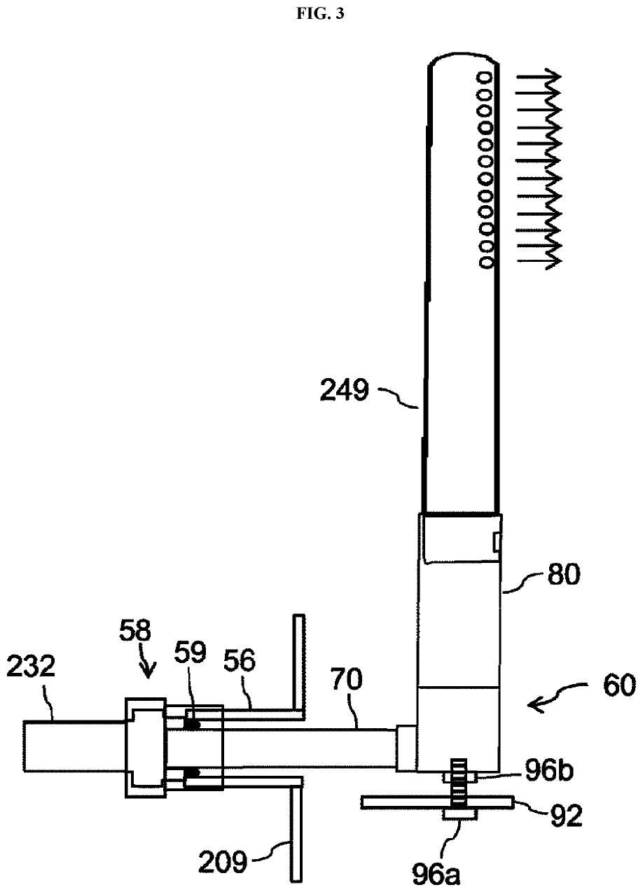

In the manifold 209 under the reaction tube 203, three port structures 56 serving as a gas introduction structure are installed so as to correspond to the nozzles 249a, 249b and 249c, respectively. Hereinafter, as shown in FIG. 3, at least one among the nozzles 249a, 249b and 249c may also be referred to as a “nozzle 249”, and at least one among the gas supply pipes 232a, 232b and 232c may also be referred to as a “gas supply pipe 232”. In addition, a port structure among the three port structures 56 corresponding to the gas supply pipe 232 and the nozzle 249 may also be referred to as a port structure 56. As shown in FIG. 3, the port structure 56 is configured as a hollow circular pipe (tube) communicating with an inside and an outside of the manifold 209 and extending horizontally toward the outside of the manifold 209. The nozzle 249 is held vertically in the process chamber 201 by the metal adapter 60. A configuration of the metal adapter 60 will be described later in detail. A support base 92 is arranged below the metal adapter 60.

Subsequently, the configuration of the metal adapter 60 will be described. As shown in FIG. 3, the metal adapter 60 includes: a horizontal structure 70 fixed to the port structure 56; and a mounting structure 80 to which the horizontal structure 70 and the nozzle 249 are attached. The nozzle 249 is provided to the mounting structure 80 in a direction perpendicular to the horizontal structure 70. The horizontal structure 70 is of a hollow circular pipe shape, is inserted into the port structure 56, and is fixed by a joint 58. An outer diameter of the horizontal structure 70 is equal to or smaller than a diameter of the port structure 56, and is smaller than an outer diameter of the gas supply pipe 232. In addition, an inner diameter of the horizontal structure 70 is substantially the same as an inner diameter of the gas supply pipe 232.

As shown in FIG. 3, the joint 58 is provided so as to cover an upstream end of the horizontal structure 70 and a downstream end of the gas supply pipe 232. The joint 58 is made of a metal, and is fixed via an O-ring 59 such that the gas supply pipe 232 communicates with the horizontal structure 70. For example, the joint 58 shown in FIG. 3 is provided at the gas supply pipe 232, and a shape of the joint 58 corresponds to an engaging structure of the horizontal structure 70 or the port structure 56 attached thereto. The joint 58 is configured to be attached or detached to the horizontal structure 70 or the port structure 56. When fixing the joint 58 to the horizontal structure 70 or the port structure 56, a fixing structure such as a screw (not shown) may be used.

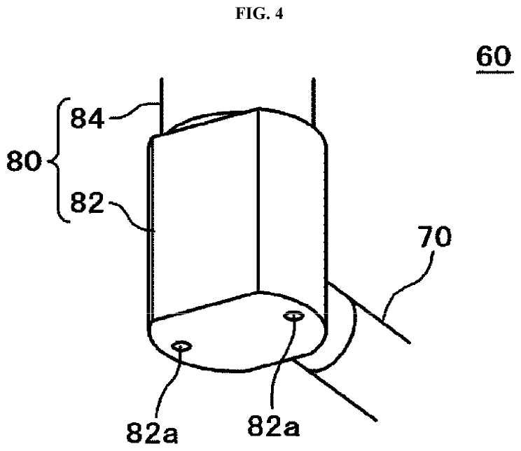

As shown in FIG. 4, the mounting structure 80 is constituted by an engaging structure 82 and an installation structure 84. The engaging structure 82 is of a shape similar to a cylinder whose two opposing side portions are cut off, and is configured to be engaged with the horizontal structure 70 on a back surface thereof (that is, a surface facing the manifold 209). The installation structure 84 is of a cylindrical shape, and is provided so as to extend upward from an upper surface of the engaging structure 82. The nozzle 249 is installed at the installation structure 84. In addition, the engaging structure 82 and the installation structure 84 are integrated as a single body made of a metal. Screw holes 82a are provided at a left portion and a right portion of a bottom surface of the engaging structure 82, respectively. That is, two screw holes 82a are provided at the bottom surface of the engaging structure 82.

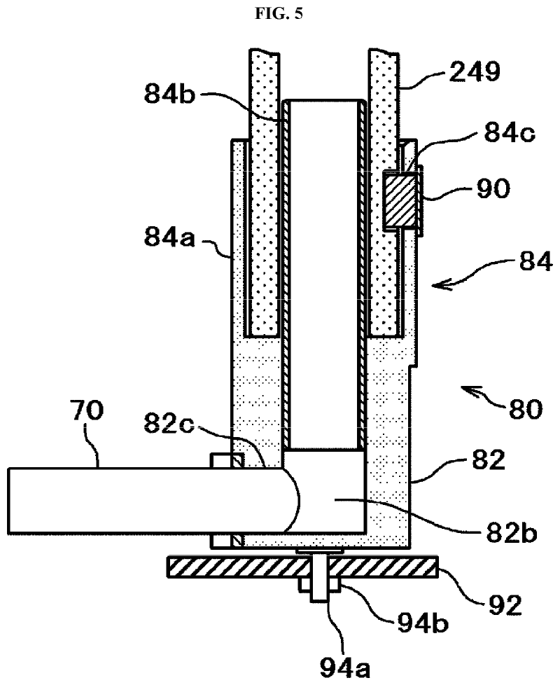

As shown in FIG. 5, the installation structure 84 is embodied by a double pipe structure including an outer pipe 84a and an inner pipe 84b, and the nozzle 249 is inserted into and fixed in an annular space between the outer pipe 84a and the inner pipe 84b. An upper end of the outer pipe 84a is provided so as to be one-step lower than an upper end of the inner pipe 84b. Further, as shown in FIG. 5, a window 84c through which a pin 90 configured to fix the nozzle 249 to the installation structure 84 is installed is provided on a front side (that is, a side facing the process chamber 201) of the outer pipe 84a at an upper portion of the outer pipe 84a. The inner pipe 84b is connected to a hollow portion 82b of the engaging structure 82 described later.

As shown in FIG. 5, the engaging structure 82 is provided with the hollow portion 82b inside thereof so as to communicate with the upper surface and the back surface of the engaging structure 82. A communication hole 82c communicating with the hollow portion 82b is provided on a side of the back surface (a surface facing the horizontal structure 70) of the engaging structure 82, and the horizontal structure 70 is inserted and fixed into the communication hole 82c. A buffer space for adjusting the tilt (horizontal degree) of the nozzle 249 is provided between the support base 92 below the engaging structure 82.

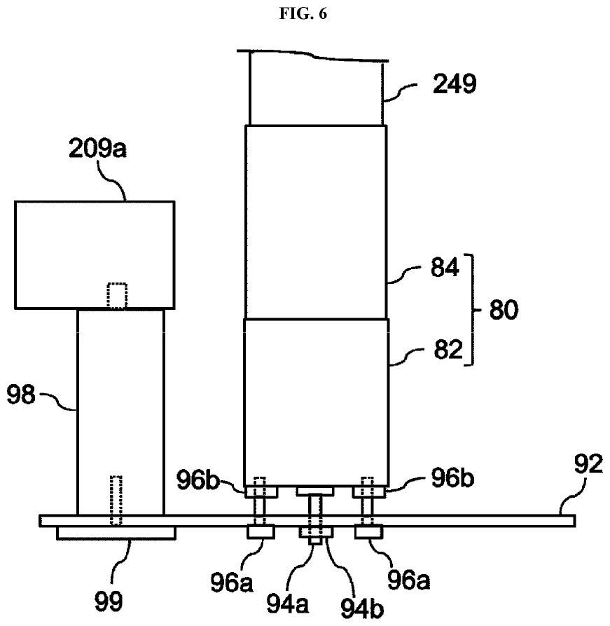

As shown in FIG. 6, the support base 92 mounted via a plurality of posts including a post 98 on a lower surface of a flange 209a of the manifold 209 is installed below the engaging structure 82 of the mounting structure 80. While only the post 98 is shown on a left portion in FIG. 6, two posts including the post 98 are provided on both the left and right portions, respectively. The bottom surface of the engaging structure 82 is substantially parallel to the lower surface of the flange 209a.

The support base 92 is provided with two holes so as to penetrate from a lower surface to an upper surface of the support base 92. The support base 92 and the mounting structure 80 are fixed by inserting two fixing bolts 96a into the two holes of the support base 92 and screwing them into the two screw holes 82a of the mounting structure 80. The fixing bolt 96a is capable of pulling the metal adapter 60 downward by engaging with the support base 92 and screwed into the metal adapter 60.

Further, the support base 92 is provided with a screw hole (not shown) so as to penetrate from the lower surface to the upper surface of the support base 92. The screw hole may be provided immediately below a center of the nozzle 249. By screwing an adjusting bolt 94a from above the support base 92, the adjusting bolt 94a can be brought into contact with a lower surface of the mounting structure 80 so as to push the mounting structure 80 upward. In addition, a nut 94b and two nuts 96b function as a locking structure for the adjusting bolt 94a and the fixing bolts 96a, and are fastened after adjusting the tilt.

The metal adapter 60 is fixed at three points by the two fixing bolts 96a and the adjusting bolt 94a. It is preferable that the two fixing bolts 96a are arranged to be point-symmetric with respect to the adjusting bolt 94a. As a result, the position and tilt of the metal adapter 60 are uniquely determined, and a rigidity of the metal adapter 60 also is increased. As for the tilt, it is possible to finely adjust a tilt in the left-right direction as well as in the front-rear direction of the metal adaptor 60, and it is also possible to prevent a contact between the process vessel and the nozzle 249 and a contact between the nozzles 249a through 249c arranged in multiple rows. By finely adjusting the tilt, a positional relationship (distance) between the nozzle 249 and the wafer 200 can be intentionally made different between an upper portion and a lower portion of the nozzle 249. Further, it is also possible to reduce a gap between the manifold 209 located at a lower portion of the process vessel and the boat 217, and it is also possible to improve a gas replacement property by reducing a volume of the process vessel.

Subsequently, a nozzle mounting method will be described. Before performing the nozzle mounting method, the boat 217 is removed in advance. When installing the nozzle 249 into the process vessel, first, the post 98 is installed on the manifold 209. Then, the adjusting bolt 94a is screwed and attached to the support base 92, and the nut 94b is loosely screwed from the lower surface of the support base 92 to a lower surface of the adjusting bolt 94a. Further, the two fixing bolts 96a are inserted into the two holes of the support base 92 from below, and the nuts 96b are screwed into upper portions of the fixing bolts 96a from the upper surface of the support base 92 such that the fixing bolts 96a are suspended from the support base 92. Then, the support base 92 and the post 98 are connected by a fixing screw 99 (step S1).

Subsequently, for example, two nozzle positioning jigs configured as a washing pinch structure are attached to two locations, respectively, (that is, the upper portion and the lower portion) of the nozzle 249 inserted and fixed in advance to the mounting structure 80 of the metal adapter 60 (step S2).

Subsequently, the horizontal structure 70 of the metal adapter 60 is inserted into the port structure 56 through a side thereof facing the process chamber 201, and further inserted into the joint 58. Then, the joint 58 temporarily fixes the horizontal structure 70 of the metal adapter 60 (step S3).

Subsequently, the mounting structure 80 is pushed upward by the adjusting bolt 94a until the nozzle positioning jigs come into contact with the reaction tube 203, and the nut 94b located below the adjusting bolt 94a and below the support base 92 is fastened (step S4). Since each front end surface of the two nozzle positioning jigs (that is, an upper nozzle positioning jig and a lower nozzle positioning jig) abuts against an inner peripheral surface of the reaction tube 203, a clearance (gap) and parallelism between the nozzle 249 and the inner peripheral surface of the reaction tube 203 are automatically adjusted and maintained. As a result, a position of the nozzle 249 in the process chamber 201 is determined.

Subsequently, the two nozzle positioning jigs are removed from the nozzle 249 (step S5).

Subsequently, the metal adapter 60 and the support base 92 are connected by screwing the two fixing bolts 96a into the two screw holes 82a of the mounting structure 80 of the metal adapter 60, respectively. When connecting the metal adapter 60 and the support base 92, the tilt of the nozzle 249 in a left-right direction may change depending on a tensile load or a tightening torque of the two fixing bolts 96a. Then, after confirming that the tilt of the nozzle 249 in the left-right direction is sufficiently small, the nuts 96b are turned toward the mounting structure 80 to fasten the fixing bolts 96a, and the joint 58 is retightened (step S6).

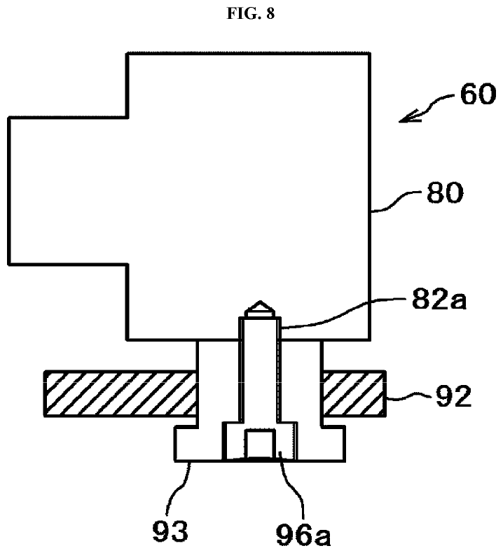

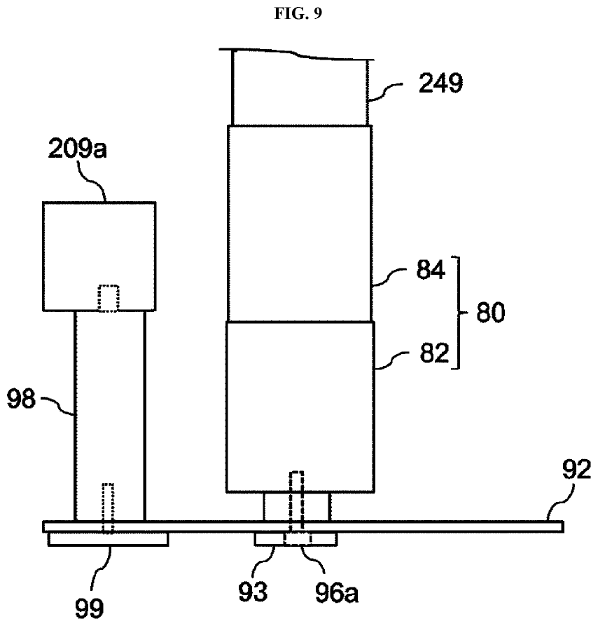

While the present embodiments are described by way of an example in which the metal adapter 60 is fixed to the support base 92 by two fixing bolts 96a, the technique of the present disclosure is not limited thereto. For example, the metal adapter 60 may be fixed to the support base 92 by one fixing bolt 96a. Another embodiment according to the technique of the present disclosure in which the metal adapter 60 is fixed to the support base 92 by one fixing bolt 96a will be described with reference to FIGS. 8 and 9.

The support base 92 is provided with a screw hole (not shown) so as to penetrate from the lower surface to the upper surface of the support base 92. By screwing an adjusting bolt 93 into the screw hole from below the support base 92, a front end (tip) the adjusting bolt 93 can be brought into contact with the lower surface of the mounting structure 80 so as to push the mounting structure 80 upward. The front end (contact surface) of the adjusting bolt 93 is configured as a plane perpendicular to a central axis of the adjusting bolt 93. That is, the front end of the adjusting bolt 93 is flat.

A bottom surface of the metal adapter 60 is substantially parallel to the lower surface of the flange 209a of the manifold 209, and one screw hole 82a is provided in its bottom surface (bottom surface of the mounting structure 80). The adjusting bolt 93 is provided with a hole (not shown) on the central axis of the adjusting bolt 93, wherein the hole penetrates from a lower surface to an upper surface of the adjusting bolt 93. The support base 92 and the mounting structure 80 are fixed by inserting the fixing bolt 96a into the hole of the adjusting bolt 93 from below and screwing it into the screw hole 82a of the mounting structure 80. The fixing bolt 96a integrates the mounting structure 80 and the adjusting bolt 93, and also prevents the adjusting bolt 93 from loosening. A verticality of the nozzle 249 is maintained by the adjusting bolt 93. It is preferable to use a screw of a sufficiently high tolerance grade to screw the support base 92 and the adjusting bolt 93. A tilt in the front-rear direction is adjusted depending on a position of the adjusting bolt 93 in the vertical direction. Since the metal adapter 60 is rigidly surface-fixed at a wide contact surface at a front end (tip) of the adjusting bolt 93, the tilt in the left-right direction can be suppressed to be small without adjustment. An outer diameter of the front end of the adjusting bolt 93 may be set to be greater than an inner diameter of the nozzle 249. Thereby, it is possible to prevent the contact between the process vessel and the nozzle 249 and the contact between the nozzles 249a through 249c arranged in multiple rows.

According to the embodiments described above, the nozzle 249 can maintain an upright posture at a predetermined position in the reaction tube 203 without contacting anything other than the mounting structure 80. As a result, it is possible to prevent particles from being generated due to the contact of the nozzle in the wafer arrangement region and its vicinity (hereinafter, also collectively referred to as a “process region”). Further, since the mounting structure 80 is mounted with a high rigidity, it is possible to prevent the nozzle from shaking or contacting due to the shaking even when the gas is discharged in a pulse-wise manner through the nozzle 249 at a large flow rate.

### (2) Substrate Processing

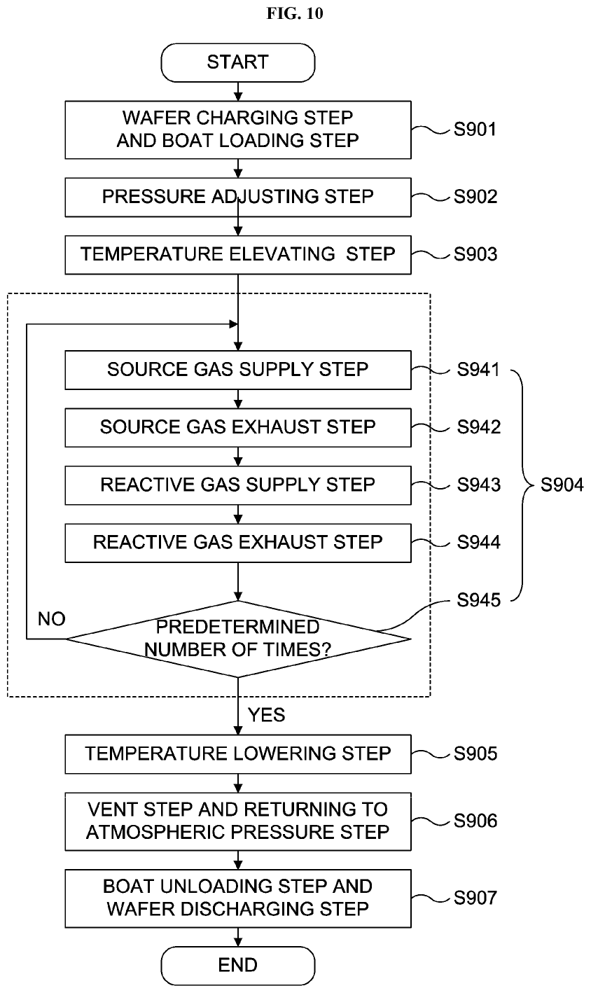

Hereinafter, an example of a substrate processing such as a film-forming process of forming a predetermined film on the wafer 200 by using a silicon-containing gas such as a silane-based gas as the source gas and a nitrogen-containing gas as the reactive gas will be described with reference to FIG. 10. In the following descriptions, the operations of the components constituting the substrate processing apparatus are controlled by the controller 121.

According to the film-forming process of the present embodiments, the film is formed on the wafer 200 by performing a cycle a predetermined number of times (at least once). For example, the cycle may include: a step S941 of supplying the source gas to the wafer 200 in the process chamber 201; a step S942 of removing the source gas (residual gas) from the process chamber 201; a step S943 of supplying the reactive gas to the wafer 200 in the process chamber 201; and a step S944 of removing the reactive gas (residual gas) from the process chamber 201. The steps S941, S942, S943 and S944 of the cycle are non-simultaneously performed.

In the present specification, the term “wafer” may refer to “a wafer itself (a bare wafer)” or may refer to “a wafer and a stacked structure (aggregated structure) of a predetermined layer (or layers) or a film (or films) formed on a surface of the wafer”. Similarly, the term “a surface of a wafer” may refer to “a surface of a wafer itself” or may refer to “a surface of a predetermined layer or film formed on the wafer, that is, a top surface (uppermost surface) of the wafer as a stacked structure”. In the present specification, the term “substrate” and “wafer” may be used as substantially the same meaning. That is, the term “substrate” may be substituted by “wafer” and vice versa.

### S901: Wafer Charging Step and Boat Loading Step

First, the wafers 200 are charged (transferred) into the boat 217 (wafer charging step). Then, the shutter 219s is moved by the shutter opener/closer 115s to open the lower end opening of the manifold 209 (shutter opening step). Thereafter, as shown in FIG. 1, the boat 217 charged with the wafers 200 is elevated by the boat elevator 115 and loaded (transferred) into the process chamber 201 (boat loading step). With the boat 217 loaded, the seal cap 219 airtightly seals the lower end of the manifold 209 via the O-ring 220b.

### S902: Pressure Adjusting Step

Thereafter, the vacuum pump 246 vacuum-exhausts (decompresses and exhausts) the inner atmosphere of the process chamber 201 such that the inner pressure of the process chamber 201 in which the wafers 200 are accommodated reaches and is maintained at a desired pressure (vacuum degree) (pressure adjusting step). When the vacuum pump 246 vacuum-exhausts the inner atmosphere of the process chamber 201, the inner pressure of the process chamber 201 is measured by the pressure sensor 245, and the APC valve 244 is feedback-controlled based on the pressure information detected by the pressure sensor 245. The vacuum pump 246 continuously vacuum-exhausts the inner atmosphere of the process chamber 201 until at least the processing of the wafer 200 is completed.

### S903: Temperature Elevating Step

The heater 207 heats the process chamber 201 such that the temperature of the wafer 200 in the process chamber 201 reaches and is maintained at a desired process temperature (temperature elevating step). When the heater 207 heats the process chamber 201, the state of the electric conduction to the heater 207 is feedback-controlled based on the temperature information detected by the temperature sensor 263 such that a desired temperature distribution of the inner temperature of the process chamber 201 can be obtained. In addition, the rotation of the wafer 200 is started by the rotator 267. The heater 207 continuously heats the wafer 200 in the process chamber 201 and the rotator 267 continuously rotates the wafer 200 until at least the processing of the wafer 200 is completed.

### S904: Film-forming Step

When the inner temperature of the process chamber 201 is stabilized at a predetermined process temperature, the film-forming step S904 is performed by sequentially performing the following four sub-steps, that is, the steps S941, S942, S943 and S944. During the film-forming step S904, the rotator 267 continuously rotates the boat 217 and the wafers 200 via the rotating shaft 255.

### S941: Source Gas Supply Step

In the source gas supply step S941, by supplying the source gas to the wafer 200 in the process chamber 201, a silicon-containing layer is formed as a first layer on an outermost surface of the wafer 200. Specifically, the valve 243b is opened to supply the source gas into the gas supply pipe 232b. A flow rate of the source gas supplied into the gas supply pipe 232b is adjusted by the MFC 241b. Then, the source gas whose flow rate is adjusted is supplied into the process region of the process chamber 201 through the gas supply holes 250b of the nozzle 249b, and is exhausted through the exhaust pipe 231 via the exhaust port 231a. In the source gas supply step S941, simultaneously, the valve 243f is opened to supply the inert gas into the gas supply pipe 232f A flow rate of the inert gas supplied into the gas supply pipe 232f is adjusted by the MFC 241f. Then, the inert gas whose flow rate is adjusted is supplied into the process region of the process chamber 201 together with the source gas through the gas supply holes 250b of the nozzle 249b, and is exhausted through the exhaust pipe 231 via the exhaust port 231a. In addition, simultaneously, the inert gas is supplied into the process region of the process chamber 201 through the gas supply holes 250a of the nozzle 249a and the gas supply holes 250c of the nozzle 249c, and is exhausted through the exhaust pipe 231 via the exhaust port 231a. In the source gas supply step S941, the controller 121 performs a constant pressure control by setting a first pressure as a target pressure.

### S942: Source Gas Exhaust Step

After the first layer is formed, the valve 243b is closed to stop the supply of the source gas into the process chamber 201, and a pressure control is performed with the APC valve 244 fully opened. As a result, the inner atmosphere of the process chamber 201 is vacuum-exhausted to remove a residual gas such as the source gas in the process chamber 201 which did not react or which contributed to the formation of the first layer from the process chamber 201. In the source gas exhaust step S942, with the valve 243f open, the inert gas may be supplied into the process chamber 201 to further purge the residual gas. A flow rate of a purge gas (that is, the inert gas) through the nozzle 249b is set such that a partial pressure of a low vapor pressure gas is lower than a saturated vapor pressure in an exhaust path, or such that a flow velocity of the gas is greater than a diffusion speed of the gas in the reaction tube 203.

### S943: Reactive Gas Supply Step

After the source gas exhaust step S942 is completed, the reactive gas is supplied to the wafer 200 in the process chamber 201 (that is, to the first layer formed on the wafer 200). In the reactive gas supply step S943, the reactive gas is thermally activated and then supplied to the wafer 200. The thermally activated reactive gas reacts with at least a portion of the first layer (that is, the silicon-containing layer) formed on the wafer 200 in the source gas supply step S941. As a result, the first layer is modified (changed) into a second layer containing silicon (Si) and nitrogen (N), that is, a silicon nitride layer. In the reactive gas supply step S943, the valves 243c and 243g are controlled in the same manners as the valves 243b and 243f in the source gas supply step S941. Specifically, a flow rate of the reactive gas is adjusted by the MFC 241c. The reactive gas whose flow rate is adjusted is then supplied into the process region of the process chamber 201 through the gas supply holes 250c of the nozzle 249c, and is exhausted through the exhaust pipe 231 via the exhaust port 231a. In addition, simultaneously, the inert gas is supplied into the process region of the process chamber 201 through the gas supply holes 250a of the nozzle 249a and the gas supply holes 250b of the nozzle 249b, and is exhausted through the exhaust pipe 231 via the exhaust port 231a. In the reactive gas supply step S943, the controller 121 performs the constant pressure control by setting a second pressure as the target pressure. For example, the first pressure and the second pressure may be set to a pressure within a range of 100 Pa to 5,000 Pa, preferably within a range of 100 Pa to 500 Pa.

### S944: Reactive Gas Exhaust Step

After the second layer is formed, the valve 243c is closed to stop the supply of the reactive gas into the process chamber 201, and the constant pressure control (that is, a fully open control) by setting a zero (0) pressure as the target pressure is performed. As a result, the inner atmosphere of the process chamber 201 is vacuum-exhausted to remove a residual gas such as the reactive gas in the process chamber 201 which did not react or which contributed to the formation of the second layer from the process chamber 201. In the reactive gas exhaust step S944, similar to the source gas exhaust step S942, a small amount of the inert gas may be supplied into the process chamber 201 as the purge gas. The ultimate pressure in the source gas exhaust step S942 or the reactive gas exhaust step S944 may be 100 Pa or less, preferably may be set to a pressure within a range of 10 Pa to 50 Pa. The inner pressure of the process chamber 201 in the source gas supply step S941 or the reactive gas supply step S943 may be different from that of the process chamber 201 in the source gas exhaust step S942 or the reactive gas exhaust step S944 by 10 times or more.

### S945: Performing Predetermined Number of Times

By performing the cycle a predetermined number of times (n times) wherein the steps S941 through S944 described above are performed sequentially and non-simultaneously in this order, the film with a predetermined composition and a predetermined thickness is formed on the wafer 200. Thicknesses of the first layer and the second layer formed in the steps S941 and S943, respectively, may not be self-limiting. Therefore, in order to obtain a stable film quality, it is preferable that a concentration of the gas exposed to the wafer 200 and a supply time (time duration) of the gas exposed to the wafer 200 are precisely controlled with a high reproducibility. In addition, the steps S941 and S942 or the steps S943 and S944 may be performed (repeated) a plurality of times within the cycle.

### S905: Temperature Lowering Step

In the temperature lowering step S905, the inner temperature of the process chamber 201 is gradually lowered when necessary, for example, by stopping the temperature elevating step S903 which is continuously performed during the film-forming step S904 or by re-setting the predetermined temperature of the temperature elevating step S903 to a lower temperature.

### S906: Vent Step and Returning to Atmospheric Pressure Step

After the film-forming step S904 is completed, the inert gas is supplied into the process chamber 201 through each of the nozzles 249a, 249b and 249c, and then is exhausted through the exhaust port 231a. The inert gas supplied through the nozzles 249a, 249b and 249c serves as the purge gas. Thereby, the process chamber 201 is purged with the inert gas such that the residual gas or reaction by-products remaining in the process chamber 201 are removed from the process chamber 201 (after-purge step or vent step). Thereafter, the inner atmosphere of the process chamber 201 is replaced with the inert gas (substitution by inert gas), and the inner pressure of the process chamber 201 is returned to the atmospheric pressure (returning to atmospheric pressure step).

### S907: Boat Unloading Step and Wafer Discharging Step

Thereafter, the seal cap 219 is lowered by the boat elevator 115 and the lower end of the manifold 209 is opened. Then, the boat 217 with the processed wafers 200 charged therein is unloaded (transferred) out of the reaction tube 203 through the lower end of the manifold 209 (boat unloading step). After the boat 217 is unloaded, the shutter 219s is moved. Thereby, the lower end opening of the manifold 209 is sealed by the shutter 219s through the O-ring 220c (shutter closing step). The processed wafers 200 are taken out of the reaction tube 203, and then discharged from the boat 217 (wafer discharging step).

### Other Embodiments

While the technique of the present disclosure is described in detail by way of the embodiments described above, the technique of the present disclosure is not limited thereto. The technique of the present disclosure may be modified in various ways without departing from the scope thereof. Those skilled in the art may widely apply the embodiments described above to a heat treatment process of the substrate under a depressurized state. For example, the technique of the present disclosure is not limited to a hot wall type reaction tube, and may be applied to a cold wall type reaction tube by using a lamp heating or induction heating. For example, the technique of the present disclosure may be applied to various types of reaction tubes such as a single tube type reaction tube shown in FIG. 1, a reaction tube with a buffer (duct) and a double tube type reaction tube.

According to some embodiments of the present disclosure, it is possible to reduce the tilt of the nozzle.

What is claimed is:

1. A substrate processing apparatus comprising:
a process vessel constituted by a reaction tube and a manifold supporting the reaction tube from thereunder and in which a substrate is processed;
a nozzle through which a process gas is supplied to the substrate;
a metal adapter configured to hold the nozzle vertically in the process vessel;
a support base arranged below the metal adapter and fixed to the manifold; and
a fixing bolt engaging with the support base and screwed into the metal adapter.

2. The substrate processing apparatus of claim 1, further comprising an adjusting bolt screwed into the support base and pushing the metal adapter upward from thereunder.

3. The substrate processing apparatus of claim 2, wherein a plurality of fixing bolts comprising the fixing bolt are arranged to be point-symmetric with respect to the adjusting bolt.

4. The substrate processing apparatus of claim 2, wherein the fixing bolt and the adjusting bolt are arranged coaxially with each other.

5. The substrate processing apparatus of claim 4, wherein the adjusting bolt is provided with a through-hole on a central axis thereof, and a front end of the adjusting bolt being in contact with the metal adapter is flat.

6. The substrate processing apparatus of claim 4, wherein an outer diameter of the adjusting bolt is greater than an inner diameter of the nozzle.

7. The substrate processing apparatus of claim 2, wherein the fixing bolt penetrates the support base or the adjusting bolt, and pulls the metal adapter downward by being screwed into the metal adapter.

8. The substrate processing apparatus of claim 2, wherein the metal adapter is surface-fixed or point-fixed at three points by the fixing bolt and the adjusting bolt.

9. The substrate processing apparatus of claim 2, wherein a bottom surface of the metal adapter is substantially parallel to a lower surface of a flange of the manifold, the fixing bolt is screwed onto the bottom surface, and the adjusting bolt and the fixing bolt are arranged coaxially with each other.

10. The substrate processing apparatus of claim 2, wherein the metal adapter allows the nozzle to communicate with a gas supply pipe provided outside the process vessel.

11. The substrate processing apparatus of claim 2, wherein the manifold comprises a port structure of a hollow circular pipe shape communicating with an inside and an outside of the manifold and extending horizontally toward the outside of the manifold.

12. The substrate processing apparatus of claim 11, wherein the metal adapter comprises:
a horizontal structure of a hollow circular pipe shape inserted into the port structure; and
a mounting structure to which the nozzle is attached and the fixing bolt is screwed.

13. The substrate processing apparatus of claim 11, wherein the support base is spaced apart from the mounting structure such that a space for adjusting a tilt of the nozzle is provided between the mounting structure and the support base.

14. A nozzle adapter comprising:
a horizontal structure of a hollow circular pipe shape inserted into a port structure of a process vessel of a substrate processing apparatus; and
a mounting structure to which a nozzle is attached along a direction perpendicular to the horizontal structure and through which the horizontal structure communicates with the nozzle,
wherein a bottom surface of the mounting structure is screwed with a fixing bolt provided on a support base fixed to the process vessel below the port structure.

15. A method of manufacturing a semiconductor device, comprising:
(a) providing a substrate processing apparatus of claim 1;
(b) loading a substrate into a process vessel of the substrate processing apparatus; and
(c) processing the substrate by supplying a gas through a nozzle of the substrate processing apparatus.

16. A substrate processing method comprising:
(a) providing a substrate processing apparatus of claim 1;
(b) loading a substrate into a process vessel of the substrate processing apparatus; and
(c) processing the substrate by supplying a gas through a nozzle of the substrate processing apparatus.
